(19) United States
(12) Patent Application Publication
(10) Pub. No.: US 2022/0300197 A1
(43) Pub. Date: Sep. 22, 2022

(54) AUTONOMOUS BACKSIDE CHIP SELECT (CS) AND COMMAND/ADDRESS (CA) TRAINING MODES

(71) Applicant: Intel Corporation, Santa Clara, CA (US)

(72) Inventors: Saravanan SETHURAMAN, Portland, OR (US); Tonia M. ROSE, Wendell, NC (US); George VERGIS, Portland, OR (US); John V. LOVELACE, Driftwood, TX (US)

(21) Appl. No.: 17/749,916

(22) Filed: May 20, 2022

(51) Int. Cl. G06F 3/06

(52) U.S. Cl. CPC G06F 3/0656; G06F 3/061; G06F 3/0673

(57) ABSTRACT

Autonomous QCS and QCA training by the RCD can remove host intervention, freeing the host to handle other tasks while the RCD trains the backside CS and CA buses. In one example, the RCD autonomously trains QCS and/or QCA signal lines by triggering the DRAMs entry into a training mode, driving the signal lines with patterns, and sweeping through delay values for the signal lines. The RCD receives training feedback from the DRAMs over a sideband bus (such as an I3C bus) and programs a delay for the one or more signal lines based on the training feedback. Thus, autonomous QCS and QCA training can reduce training time for every boot by removing host intervention and saving hose cycles.

### FIELD

Descriptions are generally related to computer memory systems, and more particular descriptions are related to training backside chip select and backside command and address signal lines.

### BACKGROUND

The standardization of many memory subsystem processes allows for interoperability among different device manufacturers. The standardization allows building devices with different architectural designs and different processing technologies which will function according to specified guidelines. Memory devices receive commands from memory controllers over command buses. In the case of buffered memory modules, a buffer device (such as a registering clock driver (RCD)) receives the command signals from the host memory controller over “frontside” signal lines and forwards or sends command signals to the memory devices over “backside” signal lines.

Typically, a host trains both the frontside and backside command signal lines to ensure that the signaling between the devices meets the expected standards. Training can refer to iterative testing of different I/O (input/output) interface parameters to determine settings that result in the best accuracy of signaling on the signal lines. With decreasing device geometries, smaller package sizes, increasing channel bandwidth, and increasing signaling frequencies, differences in design can result in variations in how signals are sent and received between a memory controller and an RCD, and between an RCD and memory device. Thus, the significant variation in memory channel layouts makes it unlikely if not impossible for memory device suppliers to guarantee the memory device will operate in its default state without training the command/address and chip select signaling. A chip select (CS) signal is used to identify a device that should execute a command on the command bus and can operate as a trigger for the sending and receiving of data and commands. CA (command and address) signals are used to communicate command and address information. Without proper I/O training, command and data transfers may be unreliable.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a block diagram of an embodiment of a memory subsystem in which autonomous RCD-controlled backside CS and CA training can be implemented.

FIG. 2 is a block diagram of a system in which autonomous RCD-controlled backside CS and CA training can be implemented.

FIG. 3 is a block diagram of an RCD with logic to perform training of the backside CS and CA signal lines.

FIG. 4 is a flow diagram of an example of a method performed by an RCD.

FIG. 5 is a flow diagram of an example of a method of autonomous training of backside signal lines by an RCD.

FIGS. 6A-6B illustrate a flow diagram of an example of a method of autonomous training of QCS signal lines by an RCD.

FIGS. 7A-7B illustrate a flow diagram of an example of a method of autonomous training of QCA signal lines by an RCD.

FIG. 8 is a block diagram of an embodiment of a computing system in which autonomous RCD-controlled backside CS and CA training can be implemented.

Descriptions of certain details and implementations follow, including a description of the figures, which may depict some or all of the embodiments described below, as well as discussing other potential embodiments or implementations of the inventive concepts presented herein.

### DETAILED DESCRIPTION

As described herein, a registering clock driver (RCD) (or other device to buffer signals between a memory controller and DRAM) autonomously trains the backside chip select (CS) and command/address (CA) bus without host involvement.

A buffered memory module, such as a buffered DIMM, is a memory module with a device that buffers signals between a host memory controller and the memory devices on the module. Examples of buffered DIMMs include registered DIMMs (RDIMMs), load-reduction DIMMs (LRDIMMs), or other DIMMs that include an RCD. The backside CS and CA signal lines are the CS and CA signal lines going from the RCD to the DRAM. The backside CS and CA are referred to herein as QCS and QCA, respectively. In contrast, the frontside CS and CA between the host memory controller and the RCD are referred to as DCS and DCA, respectively. Similarly, the backside clock signal is referred to as QCK.

Typically, the purpose of training the QCS signal lines is to adjust the QCS delay (controlled by the RCD) so that the QCK rising edge is in the middle of the QCS UI (unit interval) to maximize setup and hold margin. Traditionally, the host memory controller manages the training process for QCS and QCA signal lines. For example, the host memory controller issues MPCs (multi-purpose commands) while the RCD is set to pass through mode to cause the DRAMs to enter and later exit a CS or CA training mode. The host memory controller enables and disables various modes of the RCD throughout the QCS and QCA training. The host memory controller controls the CA patterns of the target rank. Additionally, the host is typically responsible for controlling the delays of the QCS and QCA outputs of the RCD by using register control words. Furthermore, traditionally, each signal on each DIMM is trained sequentially. Thus, conventional QCS and QCA training involves significant firmware complexity, host involvement, and time as part of the system boot process.

In contrast, autonomous QCS and QCA training by the RCD removes host intervention, freeing the host to handle other tasks while the RCD trains the backside CS and CA buses. In one example, the RCD autonomously trains QCS and/or QCA signal lines by triggering the DRAMs entry into a training mode, driving the signal lines with patterns, and sweeping through delay values for the signal lines. The RCD receives training feedback from the DRAMs over a sideband bus (such as an I3C bus) and programs a delay for the one or more signal lines based on the training feedback. Thus, autonomous QCS and QCA training can reduce training time for every boot by removing host intervention and saving hose cycles. Autonomous QCS and QCA training can remove multiple MPC in-band commands and also can enable reading training status before the DQ bus is fully trained by transmitting status over a sideband bus. Additionally, all DIMMs and all ranks can be trained in parallel to save training time.

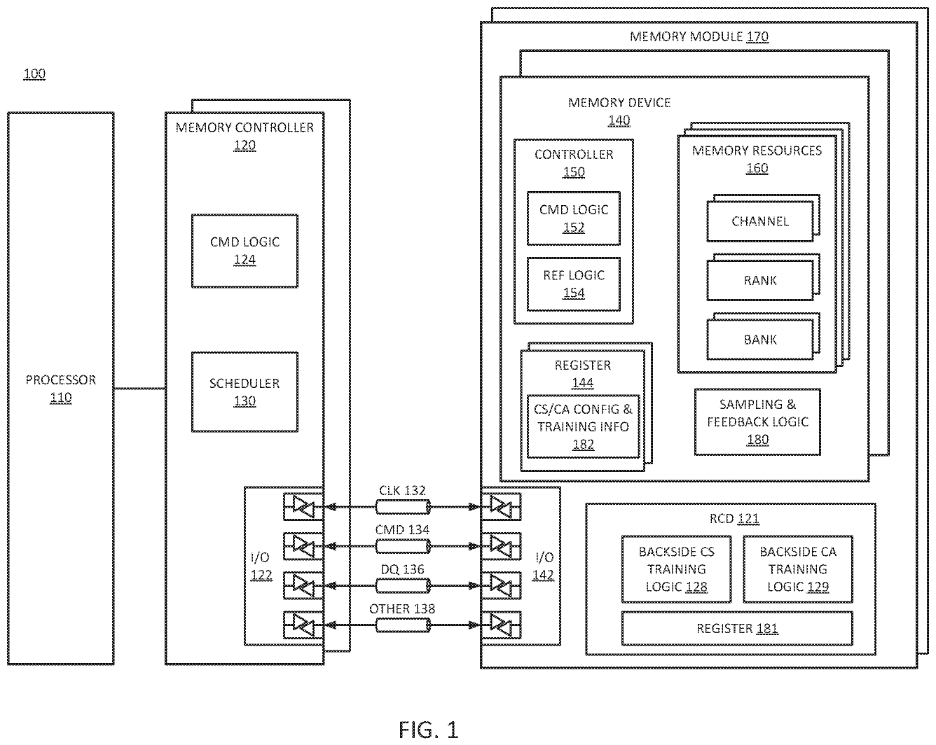

FIG. 1 is a block diagram of an embodiment of a memory subsystem in which autonomous RCD-controlled backside CS and CA training can be implemented. System 100 includes a processor and elements of a memory subsystem in a computing device. Processor 110 represents a processing unit of a computing platform that may execute an operating system (OS) and applications, which can collectively be referred to as the host or the user of the memory. The OS and applications execute operations that result in memory accesses. Processor 110 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 100 can be implemented as an SOC (system on a chip) or be implemented with standalone components.

Reference to memory devices can apply to different memory types. Memory devices often refers to volatile memory technologies. Volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, originally published in September 2012 by JEDEC), DDR5 (DDR version 5, originally published in July 2020), LPDDR3 (Low Power DDR version 3, JESD209-3B, August 2013 by JEDEC), LPDDR4 (LPDDR version 4, JESD209-4, originally published by JEDEC in August 2014), LPDDR5 (LPDDR version 5, JESD209-5A, originally published by JEDEC in January 2020), WIO2 (Wide Input/Output version 2, JESD229-2 originally published by JEDEC in August 2014), HBM (High Bandwidth Memory, JESD235, originally published by JEDEC in October 2013), HBM2 (HBM version 2, JESD235C, originally published by JEDEC in January 2020), or HBM3 (HBM version 3 currently in discussion by JEDEC), or others or combinations of memory technologies, and technologies based on derivatives or extensions of such specifications. The JEDEC standards are available at www.jedec.org.

In addition to, or alternatively to, volatile memory, in one embodiment, reference to memory devices can refer to a nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint memory device, other byte addressable nonvolatile memory devices, or memory devices that use chalcogenide phase change material. In one embodiment, the memory device can be or include multi-threshold level NAND flash memory, NOR flash memory, single or multi-level phase change memory (PCM) or phase change memory with a switch (PCMS), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

Descriptions herein referring to a “RAM” or “RAM device” can apply to any memory device that allows random access, whether volatile or nonvolatile. Descriptions referring to a “DRAM” or a “DRAM device” can refer to a volatile random access memory device. The memory device or DRAM can refer to the die itself, to a packaged memory product that includes one or more dies, or both. In one embodiment, a system with volatile memory that needs to be refreshed can also include nonvolatile memory.

Memory controller 120 represents one or more memory controller circuits or devices for system 100. Memory controller 120 represents control logic that generates memory access commands in response to the execution of operations by processor 110. Memory controller 120 accesses one or more memory devices 140. Memory devices 140 can be DRAM devices in accordance with any referred to above. In one embodiment, memory devices 140 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one embodiment, settings for each channel are controlled by separate mode registers or other register settings. In one embodiment, each memory controller 120 manages a separate memory channel, although system 100 can be configured to have multiple channels managed by a single controller, or to have multiple controllers on a single channel. In one embodiment, memory controller 120 is part of host processor 110, such as logic implemented on the same die or implemented in the same package space as the processor.

Memory controller 120 includes I/O interface logic 122 to couple to a memory bus, such as a memory channel as referred to above. I/O interface logic 122 (as well as I/O interface logic 142 of memory device 140) can include pins, pads, connectors, signal lines, traces, or wires, or other hardware to connect the devices, or a combination of these. I/O interface logic 122 can include a hardware interface. As illustrated, I/O interface logic 122 includes at least drivers/transceivers for signal lines. Commonly, wires within an integrated circuit interface couple with a pad, pin, or connector to interface signal lines or traces or other wires between devices. I/O interface logic 122 can include drivers, receivers, transceivers, or termination, or other circuitry or combinations of circuitry to exchange signals on the signal lines between the devices. The exchange of signals includes at least one of transmit or receive. While shown as coupling I/O 122 from memory controller 120 to I/O 142 of memory device 140, it will be understood that in an implementation of system 100 where groups of memory devices 140 are accessed in parallel, multiple memory devices can include I/O interfaces to the same interface of memory controller 120. In an implementation of system 100 including one or more memory modules 170, I/O 142 can include interface hardware of the memory module in addition to interface hardware on the memory device itself. Other memory controllers 120 will include separate interfaces to other memory devices 140.

The bus between memory controller 120 and memory devices 140 can be implemented as multiple signal lines coupling memory controller 120 to memory devices 140. The bus may typically include at least clock (CLK) 132, command/address (CMD) 134, and write data (DQ) and read data (DQ) 136, and zero or more other signal lines 138. In one embodiment, a bus or connection between memory controller 120 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one embodiment, independent channels have different clock signals, C/A buses, data buses, and other signal lines. Thus, system 100 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 120 and memory devices 140. An example of a serial bus technology is 8B10B encoding and transmission of high-speed data with embedded clock over a single differential pair of signals in each direction. In one embodiment, CMD 134 represents signal lines shared in parallel with multiple memory devices. In one embodiment, multiple memory devices share encoding command signal lines of CMD 134, and each has a separate chip select (CS_n) signal line to select individual memory devices.

It will be understood that in the example of system 100, the bus between memory controller 120 and memory devices 140 includes a subsidiary command bus CMD 134 and a subsidiary bus to carry the write and read data, DQ 136. In one embodiment, the data bus can include bidirectional lines for read data and for write/command data. In another embodiment, the subsidiary bus DQ 136 can include unidirectional write signal lines for write and data from the host to memory and can include unidirectional lines for read data from the memory to the host. In accordance with the chosen memory technology and system design, other signals 138 may accompany a bus or sub bus, such as strobe lines DQS. Based on design of system 100, or implementation if a design supports multiple implementations, the data bus can have more or less bandwidth per memory device 140. For example, the data bus can support memory devices that have either a ×32 interface, a ×16 interface, a ×8 interface, or other interface. The convention “xW,” where W is an integer that refers to an interface size or width of the interface of memory device 140, which represents a number of signal lines to exchange data with memory controller 120. The interface size of the memory devices is a controlling factor on how many memory devices can be used concurrently per channel in system 100 or coupled in parallel to the same signal lines. In one embodiment, high bandwidth memory devices, wide interface devices, or stacked memory configurations, or combinations, can enable wider interfaces, such as a ×128 interface, a ×256 interface, a ×512 interface, a ×1024 interface, or other data bus interface width.

In one embodiment, memory devices 140 and memory controller 120 exchange data over the data bus in a burst, or a sequence of consecutive data transfers. The burst corresponds to a number of transfer cycles, which is related to a bus frequency. In one embodiment, the transfer cycle can be a whole clock cycle for transfers occurring on a same clock or strobe signal edge (e.g., on the rising edge). In one embodiment, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length 8 (BL8), and each memory device 140 can transfer data on each UI. Thus, a ×8 memory device operating on BL8 can transfer 64 bits of data (8 data signal lines times 8 data bits transferred per line over the burst). It will be understood that this simple example is merely an illustration and is not limiting.

Memory devices 140 represent memory resources for system 100. In one embodiment, each memory device 140 is a separate memory die. In one embodiment, each memory device 140 can interface with multiple (e.g., 2) channels per device or die. Each memory device 140 includes I/O interface logic 142, which has a bandwidth determined by the implementation of the device (e.g., ×16 or ×8 or some other interface bandwidth). I/O interface logic 142 enables the memory devices to interface with memory controller 120. I/O interface logic 142 can include a hardware interface and can be in accordance with I/O 122 of memory controller, but at the memory device end. In one embodiment, multiple memory devices 140 are connected in parallel to the same command and data buses. In another embodiment, multiple memory devices 140 are connected in parallel to the same command bus and are connected to different data buses. For example, system 100 can be configured with multiple memory devices 140 coupled in parallel, with each memory device responding to a command, and accessing memory resources 160 internal to each. For a Write operation, an individual memory device 140 can write a portion of the overall data word, and for a Read operation, an individual memory device 140 can fetch a portion of the overall data word. As non-limiting examples, a specific memory device can provide or receive, respectively, 8 bits of a 128-bit data word for a Read or Write transaction, or 8 bits or 16 bits (depending for a ×8 or a ×16 device) of a 256-bit data word. The remaining bits of the word will be provided or received by other memory devices in parallel.

In one embodiment, memory devices 140 are disposed directly on a motherboard or host system platform (e.g., a PCB (printed circuit board) on which processor 110 is disposed) of a computing device. In one embodiment, memory devices 140 can be organized into memory modules 170. In one embodiment, memory modules 170 represent dual inline memory modules (DIMMs). In one embodiment, memory modules 170 represent other organization of multiple memory devices to share at least a portion of access or control circuitry, which can be a separate circuit, a separate device, or a separate board from the host system platform. Memory modules 170 can include multiple memory devices 140, and the memory modules can include support for multiple separate channels to the included memory devices disposed on them. In another embodiment, memory devices 140 may be incorporated into the same package as memory controller 120, such as by techniques such as multi-chip-module (MCM), package-on-package, through-silicon via (TSV), or other techniques or combinations. Similarly, in one embodiment, multiple memory devices 140 may be incorporated into memory modules 170, which themselves may be incorporated into the same package as memory controller 120. It will be appreciated that for these and other embodiments, memory controller 120 may be part of host processor 110.

Memory devices 140 each include memory resources 160. Memory resources 160 represent individual arrays of memory locations or storage locations for data. Typically memory resources 160 are managed as rows of data, accessed via wordline (rows) and bitline (individual bits within a row) control. Memory resources 160 can be organized as separate channels, ranks, and banks of memory. Channels may refer to independent control paths to storage locations within memory devices 140. A rank refers to memory devices coupled with the same chip select. Ranks may refer to common locations across multiple memory devices (e.g., same row addresses within different devices). Banks may refer to arrays of memory locations within a memory device 140. In one embodiment, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one embodiment, memory devices 140 include one or more registers 144. Register 144 represents one or more storage devices or storage locations that provide configuration or settings for the operation of the memory device. In one embodiment, register 144 can provide a storage location for memory device 140 to store data for access by memory controller 120 as part of a control or management operation. In one embodiment, register 144 includes one or more Mode Registers. In one embodiment, register 144 includes one or more multipurpose registers. The configuration of locations within register 144 can configure memory device 140 to operate in different “modes,” where command information can trigger different operations within memory device 140 based on the mode. Additionally, or in the alternative, different modes can also trigger different operation from address information or other signal lines depending on the mode. Settings of register 144 can indicate configuration for I/O settings (e.g., timing, termination or ODT (on-die termination), driver configuration, or other I/O settings).

Memory device 140 includes controller 150, which represents control logic within the memory device to control internal operations within the memory device. For example, controller 150 decodes commands sent by memory controller 120 and generates internal operations to execute or satisfy the commands. Controller 150 can be referred to as an internal controller and is separate from memory controller 120 of the host. Controller 150 can determine what mode is selected based on register 144 and configure the internal execution of operations for access to memory resources 160 or other operations based on the selected mode. Controller 150 generates control signals to control the routing of bits within memory device 140 to provide a proper interface for the selected mode and direct a command to the proper memory locations or addresses. Controller 150 includes command logic 152, which can decode command encoding received on command and address signal lines. Thus, command logic 152 can be or include a command decoder. With command logic 152, memory device can identify commands and generate internal operations to execute requested commands.

Referring again to memory controller 120, memory controller 120 includes command (CMD) logic 124, which represents logic or circuitry to generate commands to send to memory devices 140. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 140, memory controller 120 can issue commands via I/O 122 to cause memory device 140 to execute the commands. In one embodiment, controller 150 of memory device 140 receives and decodes command and address information received via I/O 142 from memory controller 120. Based on the received command and address information, controller 150 can control the timing of operations of the logic and circuitry within memory device 140 to execute the commands. Controller 150 is responsible for compliance with standards or specifications within memory device 140, such as timing and signaling requirements. Memory controller 120 can implement compliance with standards or specifications by access scheduling and control.

Memory controller 120 includes scheduler 130, which represents logic or circuitry to generate and order transactions to send to memory device 140. From one perspective, the primary function of memory controller 120 could be said to schedule memory access and other transactions to memory device 140. Such scheduling can include generating the transactions themselves to implement the requests for data by processor 110 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 120 typically includes logic such as scheduler 130 to allow selection and ordering of transactions to improve performance of system 100. Thus, memory controller 120 can select which of the outstanding transactions should be sent to memory device 140 in which order, which is typically achieved with logic much more complex that a simple first-in first-out algorithm. Memory controller 120 manages the transmission of the transactions to memory device 140, and manages the timing associated with the transaction. In one embodiment, transactions have deterministic timing, which can be managed by memory controller 120 and used in determining how to schedule the transactions with scheduler 130.

Referring again to the memory module 170, in one example, a buffer device 121 is included on the module 170 to buffer signals between the memory controller and the memory devices and control the timing and signaling to the DRAMs. In some examples, a buffer device is referred to as a register or a registered or registering clock driver (RCD). The term RCD is used throughout the Specification and Figures; however, the examples may apply to other buffer devices (e.g., a CXL buffer or other buffering device). For example, the examples described herein can be extended to CXL buffer-based high bandwidth DIMMs where the data buffer logic is integrated into the buffer device. The RCD 121 receives command and clock signals from the memory controller 120 and forwards them to the memory devices in accordance with relevant protocols and standard specifications. For example, the RCD 121 may be in compliance with the DDR4 Registering Clock Driver Specification (DDR4RCD02 JESD82-31A), the DDR5 Registering Clock Driver Specification (DDR5RCD02 currently in discussion by JEDEC), or other RCD standards.

Typically, during system boot, the host memory controller 120 is responsible for training the signal lines between the memory controller 120 and the memory modules 170, as well as the signal lines between the RCD 121 and the memory devices 140. Conventionally, the host controls the training of each signal line sequentially, which can require a significant amount of total time for training.

For example, to train the backside CS signal lines, the memory controller 120 issues MPC commands while the RCD 121 is set to RCD command address (CA) Pass-through mode to cause the DRAMs to enter into a chip select training mode (CSTM). The memory controller 120 then disables the RCD CA Pass-through mode and enables the RCD QCS Training Mode on the target rank. In this mode, the RCD drives QCS with a continuous clock pattern to the DRAM while sending NOP on the associated QCA signals. The memory controller 120 can use the non-target rank for controlling the delays of the QCS outputs of the RCD using register control words.

Similarly, the memory controller 120 controls the training of the backside CA signal lines in conventional systems. For example, the memory controller 120 issues MPC commands while the RCD 121 is set to RCD command address (CA) Pass-through mode to cause the DRAMs to enter into a command address training mode (CATM). In this mode, the host controls the patterns of the target rank, and uses the non-target rank for controlling the delays of the QCA outputs of the RCD using register control words. Thus, host-controlled CS and CA training adds firmware complexity and involves multiple commands from the host to manage the training process. Overall, host-controlled CS and CA training takes up more time as part of system boot time.

In contrast, RCD-controlled backside CS and CA training enables removing host intervention and allows training to be done autonomously to save host cycles and system boot time. In one such example, the RCD 121 includes one or both of backside CS training logic 128 and backside CA training logic 129. In one example, the backside CS training logic 128 includes hardware logic to manage the entire backside CS training flow. Similarly, the backside CA training logic 128 includes hardware logic to manage the entire backside CA training flow. Training can refer to the application of different parameters to determine a parameter that provides improved signaling quality. Training can include iterative operation to test different settings or parameters, which can include voltage parameters, timing parameters, or other parameters, or a combination. Iteratively applying or adjusting parameters between a minimum and maximum value is sometimes referred to as a sweep of the parameter. The sampling and feedback logic on the memory device 140 captures samples during the sweep and provides training feedback to the RCD 121.

Thus, in one example, instead of the host controlling the backside CS and CA training, the RCD 121 is responsible for triggering the memory device's entry into a training mode, generating patterns, sweeping one or more parameters for the signal lines, receiving training feedback from the memory devices, and adjusting the parameters based on the training feedback. According to one example, one or more aspects of the backside CS and CA training processes use a sideband bus between the RCD 121 and the memory device 140. For example, the RCD 121 can cause the memory device 140 to enter into a training mode and request and receive training feedback over a sideband bus.

As part of the backside CS or CA training process, the memory device and RCD 121 may store values in registers, in the memory resources 160, or both. In one example, the memory device 140 stores information regarding the samples captured by the sampling & feedback logic 180 in one or more registers 182 and/or in memory resources 160. Information about the samples may include, for example, the total count of samples captured, an indication of start and stop time for the samples, and pass/fail information. In one example, such information is provided as training feedback to the RCD 121. In one example, the RCD stores training feedback in a register 181. The final parameters selected as a result of training may also be stored in register 181, register 182, or both.

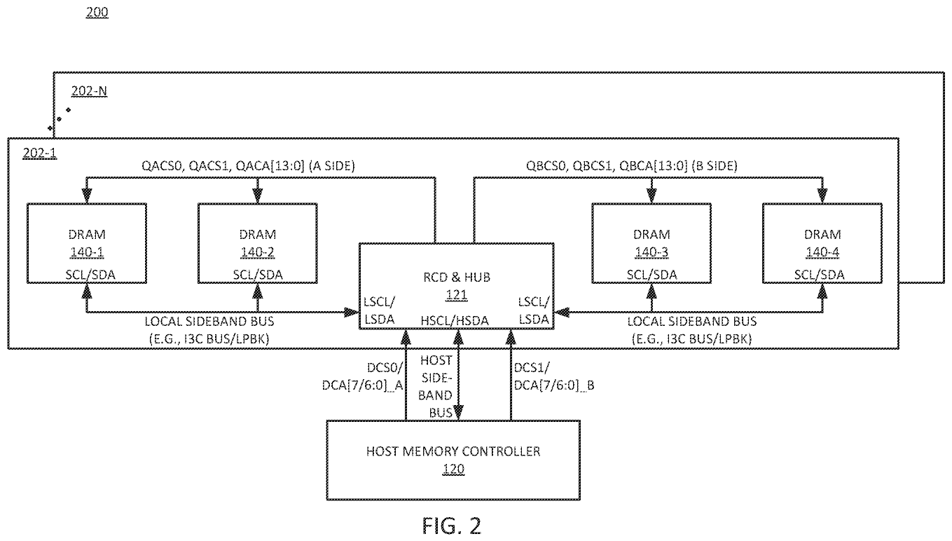

FIG. 2 is a block diagram of a system 200 in which autonomous RCD-controlled backside CS and CA training can be implemented. The system 200 includes multiple dual inline memory modules (DIMMs) 202-1-202-N coupled with a host memory controller 120. The DIMMs 202-1-202-N can be the same as or similar to the memory module 170 of FIG. 1. Each of the DIMMs 202-1-202-N includes a plurality of DRAM chips or devices. For example, the DIMM 202-1 includes DRAM chips 140-1-140-4. The example in FIG. 2 illustrates four DRAM chips; however, other examples may include fewer than or more than four DRAM chips.

Each of the DIMMs 202-1-202-N also includes an RCD 121. The RCD 121 receives and buffers a clock signal, CA signals, and CS signals from the host memory controller 120. The CS signals from the host are designated as DCS0 and DSC1 in FIG. 2. Thus, in the illustrated example, the RCD 121 has two DCS inputs per channel. Similarly, the CA signals from the host are designated as DCA_A and DCA_B in FIG. 2. In the example in FIG. 2, the host-RCD CA interface is 8 bits (7 bits plus parity), and the RCD-DRAM CA interface is 14 bits. Thus, in one example, the RCD 121 expands the DCA bus to 14 bits at the interface with the DRAMs. Other examples may include interfaces having different sizes than the example of FIG. 2.

DCA_A and QACA represent CA signals going to an “A side,” and DCA_B and QBCA represent CA signals going to a “B side” of the DIMM. The A side refers to one group of DRAM devices on the DIMM, and the B side refers to another group of DRAM devices on the DIMM. The DRAMs may be organized into different groupings or sides (e.g., all in one group or in more than two groups). The DCA and DCS signals are often referred to as “frontside” signals because they are between the host memory controller 120 and the RCD 121. The QCA and QCS signals are often referred to as “backside” signals because they are between the RCD and the DRAMs.

According to one example, the RCD forwards the CS and CA signals from the host to the DRAMs, with exceptions. For example, in normal operation, the RCD 121 forwards the DCA signals to the DRAMs as QCA signals when a DCA input is active. However, if a parity error is detected or if the RCD 121 is in a mode to block forwarding of the CA or CS signals, the RCD 121 may prevent one or more of the signals from being forwarded to the DRAMs. If the RCD 121 is in a pass-through mode (e.g., CA Pass-through mode), then the RCD 121 will pass the CA signals from the host to the DRAMs even if a parity error is detected.

In addition to the CS and CA signals, each of the DIMMs 202-1-202-N receives sideband bus signals from the host memory controller 120 over a host sideband bus. In the illustrated example, the RCD 121 includes host sideband clock (HSCL) and host sideband data (HSDA) pins for sending and receiving signals over the host sideband bus. In one example, the host sideband bus is in compliance with one or more sideband bus standards, such as the JEDEC Module SidebandBus Specification (e.g., version 1, JESD403-1, originally published January 2020), a MIPI I3C standard specification (e.g., MIPI I3C version 1.1.1, published Jun. 8, 2021, MIPI I3C Basic version 1.1.1, published Jun. 9, 2021, or other I3C specification), and/or other sideband bus standards. In the illustrated example, the RCD 121 also operates as a sideband bus hub. In one example, a sideband bus hub is a device that isolates loads on the sideband bus (e.g., on the I3C basic bus), increasing the number of supported devices on a bus. Thus, in one example, the hub provides pull-up voltages on the local bus data lines. In one example, the hub includes logic to redrive the signals from the host-side sideband bus to the local sideband bus between the hub and other devices on the local bus. Although FIG. 2 illustrates an example in which the RCD and hub are implemented in the same physical device or die, the hub may be implemented separately from the RCD.

In addition to the sideband bus between the RCD and the host, the DIMMs 202-1-202-N include one or more local sideband buses between the RCD 121 and the DRAMs on the DIMM. In the example illustrated in FIG. 2, the DIMM 202-1 includes a first I3C bus between the RCD 121 and the DRAMs 140-1-140-2 and a second I3C bus between the RCD 121 and the DRAMs 140-3-140-4. In the example illustrated in FIG. 2, the RCD 121 includes local sideband clock (LSCL) and local sideband data (LSDA) pins coupled with the local sideband buses. Similarly, the DRAMs also include pins (e.g., SCL and SDA) coupled with the local sideband bus. In one such example, the sideband bus between the RCD 121 and the DRAMs is in compliance with one or more sideband bus standards, such as the JEDEC Module SidebandBus Specification (e.g., version 1, JESD403-1, originally published January 2020), a MIPI I3C standard specification (e.g., MIPI I3C version 1.1.1, published Jun. 8, 2021, MIPI I3C Basic version 1.1.1, published Jun. 9, 2021, or other I3C specification), and/or other sideband bus standards. In one example, in addition to SCL and SDA pins, other pins (such as loopback (LPBK) pins) may be used for sending or receiving signals over the I3C bus.

In one example, unlike in conventional systems, the RCD 121 handles the training of the backside CS and CA signal lines. Note that although examples refer to RCD-controlled training of both the backside CS signal lines and the backside CA signal lines, the RCD may control the training of only one or both of the backside CS and CA signal lines. Also note that while some examples refer to an RCD, the examples also apply to other buffer devices between a host memory controller and memory.

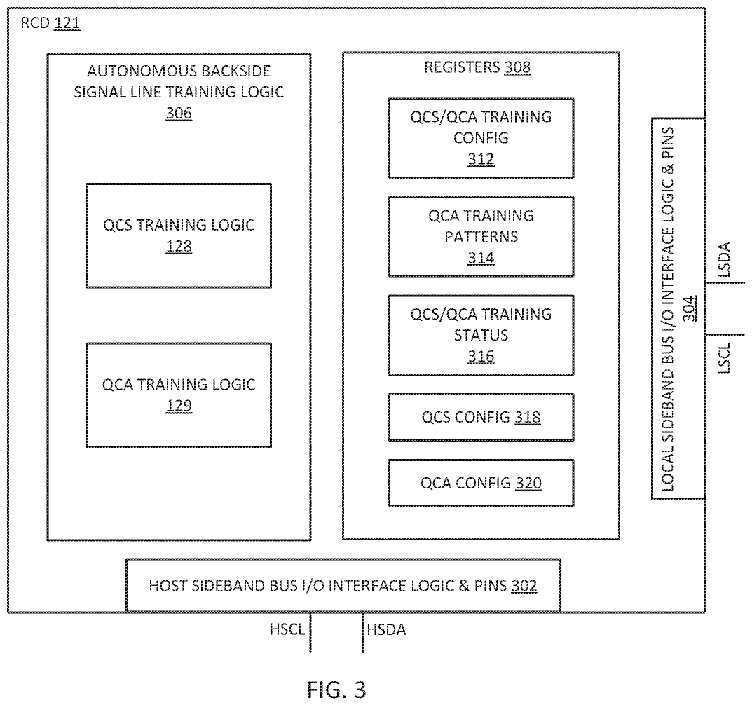

FIG. 3 is a block diagram of an RCD with logic to perform training of the backside CS and CA signal lines. The RCD includes interface logic and pins for sending and receiving signals over the sideband buses. For example, the RCD 121 includes host sideband bus interface logic and pins 302 and local sideband bus interface logic and pins 304. According to one example, the host sideband bus interface logic 302 includes two pins (HSCL and HSDA) for coupling with one host sideband bus. In other examples, the RCD 121 may include more than two pins for coupling with one or more host-side sideband buses. The local sideband bus interface logic 304 includes at least two pins (LSCL and LSDA) for coupling with a local sideband bus. In other examples, the RCD may include more than two local sideband bus pins for coupling with multiple sideband buses (e.g., two or more pins coupled to each local sideband bus).

The RCD 121 includes logic 306 for training the backside CS and CA signal lines. The illustrated example includes both QCS training logic 128 and QCA training logic 129; however, in other examples, the RCD may be responsible for autonomously training only the QCS signal lines or only the QCA signal lines. In one such example, the host may control training of any backside signal lines not trained by the RCD. In one example, the logic 306 of the RCD 121 trains one or more backside signal lines by triggering the DRAMs to enter into a training mode, driving the one or more signal lines with patterns, and iteratively adjusting parameters (e.g., sweeping a parameter). The logic 306 then programs one or more parameters based on the training feedback from the DRAMs.

The RCD 121 includes one or more registers 308 to facilitate training and store parameters. For example, the RCD 121 of FIG. 3 includes a register 312 to store QCS training configuration information, QCA training configuration, or both. QCS and QCA training configuration information can include: enable/disable bits to enable or disable RCD-controlled QCS or QCA training, the number of training samples to be captured by the DRAMs during QCS or QCA training, the sampling or counting window for QCS or QCA training, the number of training sweeps to perform for QCS or QCA parameters, and other training configuration information. In one such example, the host memory controller (e.g., memory controller 120 of FIG. 1) programs the QCS and QCA training configuration registers.

As mentioned above, in one example, the RCD 121 is responsible for generating patterns for training the QCA signal lines. In one such example, the RCD 121 includes one or more registers 314 for storing training patterns. The RCD 121 also includes one or more status registers 316 to store training feedback and status received from the DRAMs. Examples of training feedback from the DRAMs can include: total count of the samples captured, an indication of start and stop time for the samples, and pass/fail information, and other training feedback. The training feedback can be stored for each QCS and each QCA signal line as individual samples, as an averaged value, or as an aggregate value. After the RCD 121 receives the training feedback from the DRAMs, the logic 306 determines which parameter values to use based on the feedback and programs the config registers 318 and 320 with values to indicate the selected parameter values for the QCS and QCA signal lines, respectively.

In one example, the RCD 121 uses a sideband bus between the RCD 121 and the DRAMs to send and receive training information. For example, the RCD 121 can put the DRAMs in a training mode by sending one or more commands over the sideband bus. The RCD 121 can also receive training feedback from the DRAMs over the sideband bus instead of over the DQ signal lines. After training the DRAMs, the RCD can cause the DRAMs to exit from a training mode by sending one or more commands over the sideband bus.

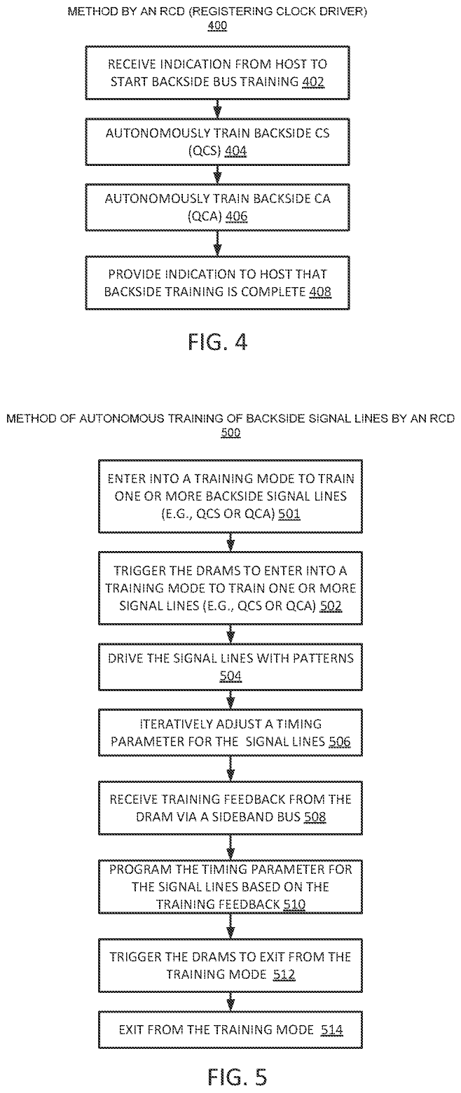

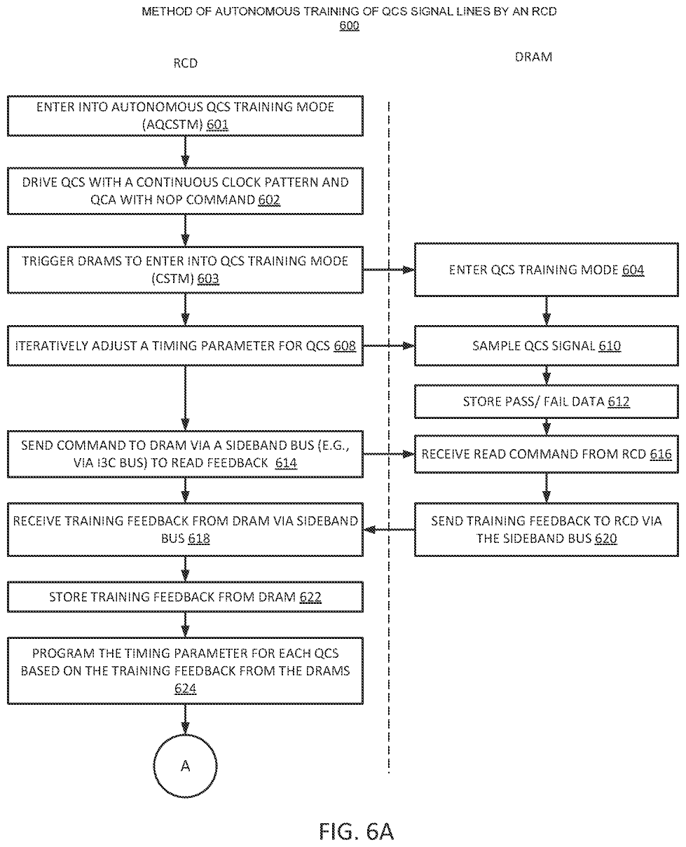

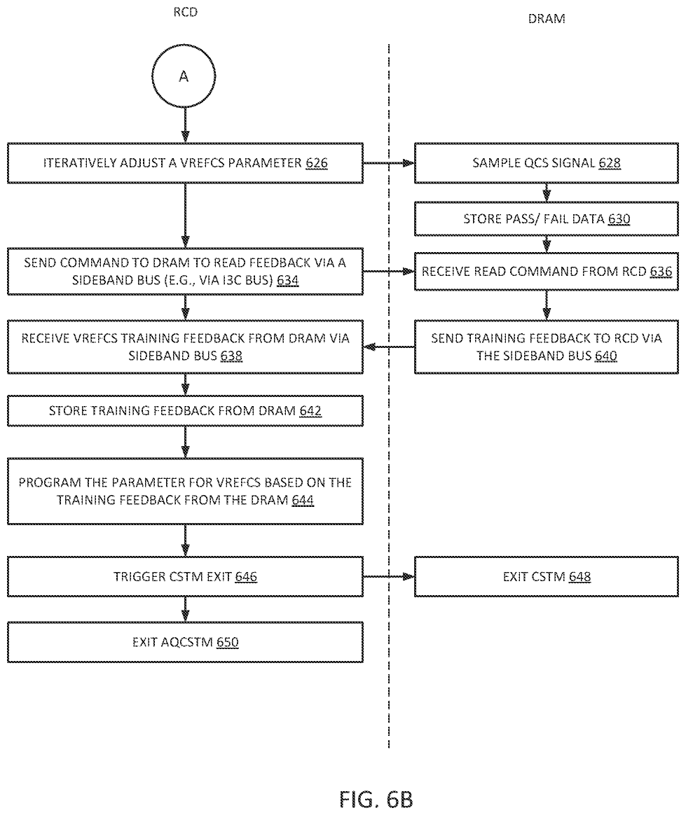

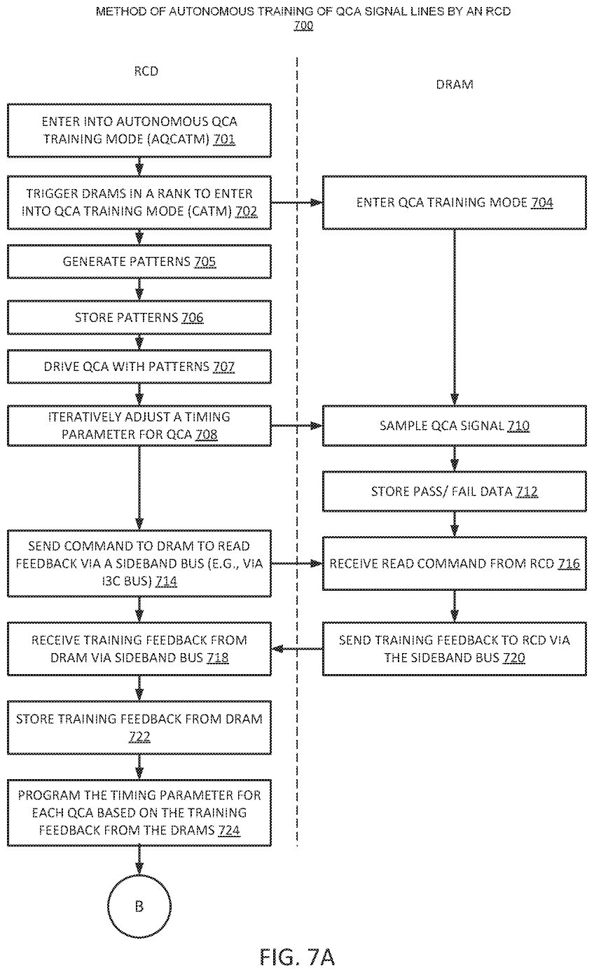

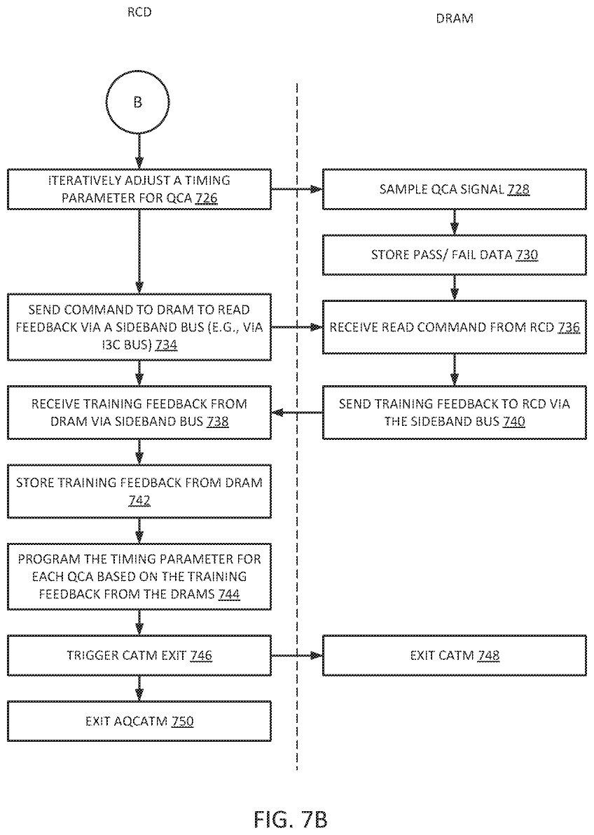

FIGS. 4, 5, 6A, 6B, 7A, and 7B are flow diagrams illustrating examples of methods of RCD-controlled backside signal line training. FIGS. 4 and 5 illustrate examples of methods performed at or by an RCD. FIGS. 6A, 6B, 7A, and 7B illustrate examples of methods from both the RCD and DRAM perspectives. In one example, methods performed at or by an RCD are performed with hardware logic of the RCD (interface logic 302, interface logic 304, and training logic 306 of FIG. 3). Similarly, in one example methods performed at or by a DRAM device are performed by hardware logic of the DRAM device (e.g., logic 180 of FIG. 1).

Referring to FIG. 4, the method 400 starts with receiving an indication from the host to start backside bus training, at block 402. In one example, the host memory controller sends one or more commands to indicate that the RCD is to start backside bus training, including training the QCS and/or QCA signal lines. Triggering the RCD to start backside bus training may involve causing the RCD to enter into a training mode. In one such example, the host memory controller sends one or more commands over a host sideband bus (e.g., I3C bus or SMBus). For example, referring to FIG. 2, the host memory controller 120 can send one or more commands over the host sideband bus to the RCD 121 to trigger the RCD to start backside bus training. In another example, the RCD may perform the backside bus training as a part of reset or power-up initialization process.

Referring again to FIG. 4, the RCD autonomously trains the QCS signal lines, at block 404. For example, referring to FIGS. 1 and 2, the QCS training logic 128 autonomously trains the QCS signal lines (e.g., QACS0, QACS1, QBCS0, and QBCS1). Autonomously training the backside signal lines refers to training by the RCD without direct involvement by the host (except for, in some examples, initiating the backside training process and programming configuration registers that may affect training). For example, when the RCD autonomously trains the backside signal lines, the RCD controls the DRAM's entry into and exit from a training mode, drives patterns on the signal lines, receives training feedback from the DRAMs, and programs parameters based on the training feedback without commands from the host to control those operations.

In one example, after training the QCS signal lines, the RCD trains the QCA signal lines, at block 406. For example, referring to FIGS. 1 and 2, the QCA training logic 129 autonomously trains the QCA signal lines (e.g., QACA and QBCA). After training the QCS and QCA signal lines, the RCD provides an indication to the host that backside training is complete, at block 408. Providing an indication to the host that backside bus training is complete may involve, for example, updating a status register that can be read by or polled by the host. For example, referring to FIG. 3, the RCD can set the QCS/QCA training status register 316 to indicate that QCS and QCA training is complete. In one such example, the host memory controller can read the register 316 via commands sent over the host sideband bus. In one example, if the I3C bus is shared, then the registers are shadowed so that host can read without interrupting RCD operations. In one example, a baseboard management controller (BMC) can read the status of the backside CS or CA training by reading an exposed calibration status register over the I3C bus.

In one example, the RCD trains signal lines on multiple sides of the DIMM in parallel. For example, referring to FIG. 2, the RCD 121 can train the A side signals (e.g., QACS0 and QACS1 or QACA) and the B side signals (e.g., QBCS0 and QBCS1 or QBCA) in parallel. Thus, in one example, the RCD 121 can train signal lines for multiple sides of a memory module in parallel, wherein the multiple sides include multiple copies of the same type of signals to different DRAMs on the memory module.

FIG. 5 is a flow diagram of an example of a method 500 of autonomously training backside signal lines by an RCD. In one example, the one or more signal lines to train include one or more chip select (CS) signal lines or one or more command/address (CA) signal lines. Thus, the method 500 is an example of the operations at block 404 and 405 of FIG. 4.

The method 500 starts with entering into a training mode to train one or more backside signal lines, at block 501. For example, referring to FIG. 3, the RCD 121 enters an autonomous QCS or QCA training mode. The autonomous QCS training mode may be referred to as AQCSTM or QCSTM. The autonomous QCA training mode may be referred to as AQCATM or QCATM. The RCD can enter into the autonomous QCS or QCA training mode in response to a trigger from the host, in response to reset or power-up initialization, or in response to another trigger to train QCS or QCA.

After the RCD enters the training mode, the RCD triggers the DRAMs to enter into a training mode to train one or more signal lines, at block 502. In one example, triggering or causing the DRAMs to enter into a training mode involves the RCD sending one or more commands to the DRAMs over a sideband bus. For example, referring to FIGS. 2 and 3, hardware logic 306 of the RCD 121 can send one or more commands over the local I3C bus to the DRAM to trigger the DRAM to enter a training mode. In one example, if the signal lines being trained by the RCD are QCS signal lines, then the RCD 121 triggers the DRAMs to enter into a CS training mode. Similarly, in one example, if the signal lines being trained by the RCD are QCA signal lines, the RCD triggers the DRAMs to enter into a CA training mode.

Referring again to FIG. 5, the RCD drives the signal lines with patterns, at block 504. For example, referring to FIG. 3, the QCS training logic 128 or the QCA training logic 129 causes patterns to be driven on the QCS signal lines and QCA signal lines. The patterns driven on the signal lines depend on which signal lines the RCD is training. In one example, the patterns that the RCD drives on the signal lines also depend on settings indicated in training configuration registers (e.g., the register 312 of FIG. 3).

In one example, to train the QCS signal lines, the RCD drives the QCS signal lines with a continuous clock pattern to the DRAM while sending an equivalent NOP command on the associated QCA signal lines. Thus, unlike in conventional QCS training, the RCD sets the QCA signal lines to the right level for a NOP command instead of the host sending NOP commands. In another example, to train the QCA signal lines, the RCD generates a pattern which can be a simple fixed pattern or a more complex LFSR pattern. In one such example, the RCD may perform multiple sweeps with different patterns (e.g., first a simple fixed pattern followed by a complex pattern). In one example, the type of pattern and number of sweeps can be determined by reading a QCA training config register, such as the register 312 of FIG. 3. Thus, unlike in conventional QCA training, the RCD generates the patterns driven on the QCA signal lines instead of the host.

Referring again to FIG. 5, the RCD iteratively adjusts (i.e., sweeps) a timing parameter for the signal lines being trained, at block 506. A timing parameter can include a delay in the signal. Iteratively adjusting a timing parameter involves driving the signal lines with patterns with different timing parameters selected from a predetermined range of timing parameters. For example, referring to FIG. 3, the QCS training logic 128 or the QCA training logic 129 can iteratively apply different timing parameters from a lowest/minimum value to a highest/maximum value (or a highest value to a lowest value). The DRAMs can then take samples at the different timing parameter values and provide feedback regarding which timing parameter values pass or fail.

In one example, the RCD receives the training feedback from the DRAMs via a sideband bus, at block 508. For example, referring to FIG. 2, the RCD 121 sends a command to request training feedback from the DRAMs over the local I3C bus, and the training feedback is received in response to the read command sent to the DRAM over the local I3C bus. Thus, unlike in conventional QCS and QCA training, the RCD can receive training feedback prior to data bus (DQ) training because the training feedback is not sent to the host via the DQ lines. In one example, the RCD stores the training feedback in one or more registers. For example, referring to FIG. 3, the QCS training logic 128 or QCA training logic 129 stores training feedback in the QCS/QCA training status register 316.

In one example, the training feedback from the DRAM includes pass/fail data for one or more samples captured by the DRAM at different timing parameter values. The training feedback received from the DRAMs can include pass/fail data for each of the parameter values (e.g., for each of the delay values) swept through, or the RCD can receive the training feedback as an aggregate or average for the parameter values. The RCD can receive the training feedback from multiple DRAMs in parallel or serially. Based on the training feedback, the RCD programs the timing parameter for the signal lines, at block 510. For example, referring to FIG. 3, the QCS training logic 128 or the QCA training logic 129 programs a configuration register 318 or 320 with a value to configure a timing parameter based on the training feedback.

In one example, in addition to performing training for QCS or QCA timing parameters, the RCD can perform training for a reference voltage for QCS or QCA (e.g., VrefCS or VrefCA). In one such example, referring to FIGS. 2 and 3, after programming the delay for the one or more signal lines, the QCS training logic 128 or QCA training logic 129 of the RCD 121 sends one or more commands over the local I3C bus to sweep through Vref values for QCS or QCA, respectively. In one example, the Vref values swept through are different voltages, which may be defined as a percentage of VDD or by another function of VDD. The logic 128 or 129 of the RCD 121 can then receive Vref training feedback from the DRAM and program Vref based on the Vref feedback. Thus, in addition to training a timing parameter for QCS and QCA, the RCD can also train Vref to determine optimal parameter values for the DRAM.

Referring again to FIG. 5, to complete the training for the backside signal lines, the RCD triggers the DRAMs to exit from the training mode, at block 512. In one example, referring to FIGS. 2 and 3, the QCS training logic 128 or the QCA training logic 129 sends one or more commands to the DRAM over the local I3C bus to cause the DRAM to exit from a training mode. The RCD can then exit from the training mode, at block 514. Note that some of the operations of the method 500 of FIG. 5 can be performed multiple times to improve the training outcome. For example, QCA can be trained with different patterns by repeating the operations in blocks 504-508 prior to selecting and programming the optimal parameters for the signal lines at block 510.

FIGS. 6A-6B illustrate a flow diagram of an example of a method 600 of RCD-controlled training of QCS. The method 600 is similar to the method 500 of FIG. 5, but with exemplary details specific to training QCS.

The method 600 begins with the RCD entering into an autonomous QCS training mode (AQCSTM), at block 601. In one example, the RCD is triggered to enter the AQCSTM by the host (e.g., in response to one or more commands from the host to perform backside bus training generally, or QCS training specifically, or other commands from the host). For example, referring to FIGS. 2 and 3, the host memory controller 120 sends one or more commands to the RCD 121 to trigger the RCD to enter into a backside training mode. In the backside training mode, the RCD 121 autonomously trains QCS.

After entering the AQCSTM, in one example, the RCD autonomously performs the initialization sequence to prepare the DRAM for QCS training. In one example, the RCD uses I3C commands to the DRAM, although legacy MPC in-line commands can be used for debug and to override RCD control. In one such example, after BCOM training and Per DRAM Addressability (PDA) Enumeration, RCD internal logic (e.g., logic 306 of FIG. 3) sets signals at the right level which is equivalent to a NOP command to initiate QCS training mode within a backside training mode. In one example, the RCD drives QCS with a continuous clock pattern to the DRAM while sending an equivalent NOP command on the associated QCA signals, at block 602. Having the RCD drive the signals to the correct levels for a NOP command removes the dependency on the host to send NOP commands.

In one example, for each Rank, the RCD sends a NOP equivalent command/tie signals high for a minimum of three cycles as required by the DRAM initialization sequence. In one example, the RCD sends I3C commands to the DRAM through the sideband bus to execute ZQCal Start (to initiate the calibration procedure) and ZQCal Latch (to capture the result and load it). In one example, the RCD configures the DRAM with the help of strap settings, NVM storage, and/or I3C commands with initial settings such as VrefCA, VrefCS, and termination settings such as RTT. In one such example, the RCD initially sets a default value for VrefCA and VrefCS during the first training run. As explained in more detail below, the RCD can sweep VrefCS values and perform the QCS training multiple times to determine more accurate or optimal Vref settings. In one such example, the RCD can perform an accelerated autonomous VrefCS sweep to find a better Vref value. In one example, the RCD is also set to block commands to the data buffers (DB), and to forward commands to the DRAM as safety measures.

Referring again to FIG. 6A, in one example, the RCD triggers the DRAMs to enter into a QCS training mode (CSTM), at block 603. In one example, causing the DRAMs to enter into a QCS training mode involves sending one or more commands over a local sideband bus. For example, referring to FIGS. 2 and 3, the QCS training logic 128 of RCD puts the DRAM in CSTM by sending I3C commands to DRAM. In response to receiving the one or more commands from the RCD to enter into the QCS training mode, the DRAM enters the QCS training mode, at block 604.

The RCD then iteratively adjusts a timing parameter for QCS, at block 608. For example, referring to FIG. 3, the RCD 121 sweeps the QCS (e.g., QxCSx) delays of a particular Rank. In one such example, sweeping the QCS delays involves adjusting the delay from 0-127 with a programmable step size. In one such example, the RCD adjusts the QCS delay by modifying control words (e.g., register settings) in the RCD (e.g., control words RW12-RW1A(RCD)/RW82(DB) as defined in the in JEDEC DDR5RCD Specification).

While the RCD is sweeping a timing parameter for QCS, the DRAM samples the QCS signal, at block 610. In one example, once the DRAM has CSTM enabled, the DRAM device begins sampling on every rising CK edge, starting with a rising edge of clock signal after a delay of tCSTM_Entry. In one such example, the RCD and/or the DRAM can be programmed to count the number of samples and programmed with a sampling or counting window (e.g., how long the DRAM has to sample the QCS signal lines). Programming the RCD with a sampling window or other training parameters can involve programming a QCS training configuration register (e.g., register 312 of FIG. 3). Programming the DRAM with training configuration details can involve programming a training configuration register (e.g., register 182 of FIG. 1). In one example, the DRAM stores information from the training, such as pass/fail data, in a register on the DRAM, at block 612. For example, referring to FIG. 1, the DRAM sampling and feedback logic 180 stores the pass/fail data in a register (e.g., the register 182).

In one example, after iteratively adjusting the timing parameter for QCS, the RCD receives feedback from the DRAM through the I3C/LPBK pins by doing an I3C read. For example, referring to FIG. 6A, the RCD sends one or more commands to the DRAM via a sideband bus to read feedback, at block 614. For example, referring to FIGS. 2 and 3, the QCS training logic 128 sends one or more read commands over the local I3C bus to the DRAM via the I3C pins (LSDA and LSCL). The DRAM receives the read command from the RCD, at block 616, and sends training feedback to the RCD via the sideband bus, at block 620. For example, the DRAM sends pass/fail data for one or more samples captured by the DRAM. As mentioned above, the pass/fail data can be provided to the RCD for every delay from the sweep, in aggregate, or as an average.

In one example, the DRAM sends the data over the I3C bus via the DRAM's I3C pins (SDA and SCL) and/or the Loopback pins (LPBK). In one example, the DRAM side LPBK pins must be in an I3C time division multiplexing (TDM) mode. In one such example, by default, DRAM pins will be in an I3C mode and until the training is complete, the RCD does not switch between the I3C mode and LPBK mode in the DRAM. Thus, in one example, during training, the LPBK pins are in I3C mode. Logic in the DRAM puts the sampled data into an I3C packet and sends it to the RCD. The LPBK pins can be used in LPBK mode for electrical validation, measurement, and debug. In one example, each DRAM for which QCS is being trained will send the feedback through LPBK pins simultaneously, which is handled by an I3C arbiter in the RCD.

Referring again to FIG. 6A, once the RCD receives the training feedback from the DRAM via the sideband bus, at block 618, the RCD can store the feedback at block 622. For example, referring to FIG. 3, the QCS training logic 128 can store the training feedback in a QCS training status register (e.g., register 316). In one example, the RCD counts errors and stores failure details (Cal status) for debug purposes in the QCS training status register. In one example, the RCD performs an I3C read for every timing point. In another example, to reduce the number of I3C reads, the samples are stored locally within DRAM itself and aggregated or averaged after a timing point. The average or aggregation can then be output by the DRAM as a single value over the local I3C bus.

The RCD also determines a timing parameter value to use based on the training feedback and programs the timing parameter for each QCS, at block 624. For example, referring to FIG. 3, the QCS training logic 128 determines the delay that that is optimal based on the training feedback and programs a QCS configuration register 318 to select that value. In one such example, calculating final delay settings involves determining: centering=(LE+RE)/2.

Once the timing parameter is programmed, the RCD can also perform a sweep of the reference voltage for QCS (VrefCS). For example, referring to FIG. 6B, the RCD can iteratively adjust a VrefCS parameter, at block 626. In one example, iteratively adjusting the VrefCS parameter involves sending write commands to one or more registers in the DRAM to adjust the VrefCS parameter. In one example, the VrefCS parameter swept by the RCD is the voltage level. As mentioned above, the VrefCS voltage level can be indicated as a value relative to VDD (e.g., a percentage or other function of VDD). The DRAM samples the QCS signal, at block 628, and stores pass/fail data, at block 630. The RCD can then request training feedback from the DRAM by sending one or more commands (e.g., a read command) over the sideband bus, at block 634. The DRAM receives the read command from the RCD, at block 636, and sends the requested training feedback to the RCD via the sideband bus, at block 640. The RCD receives the training feedback for the VrefCS sweep, at block 638, and stores the training feedback from the DRAM, at block 642. The RCD can then program the VrefCS parameter based on the training feedback, at block 644.

The RCD can then trigger the DRAM to exit from the CSTM mode, at block 646. Triggering the DRAM to exit from the CSTM mode can involve, for example, the RCD sending one or more commands to the DRAM over the I3C bus to trigger the exit from CSTM. In response to the command from the RCD, the DRAM exits CSTM, at block 648.

The RCD can train QCS all ranks in parallel, or one rank at a time. For example, if the RCD is training one rank at a time, the RCD causes the DRAMs in a particular rank to exit the CSTM and moves on to the other rank to repeat operations 602-646. After training all ranks, the RCD exits the AQCSTM on the RCD, at block 650, and can program the RCD with the final results (e.g., corresponding delays for each QCS, setup and hold time for each QCS, or other final information from training). In one example, the host can read the status of the QCS training through the I3C bus (e.g., the host I3C bus) due to the DQ bus not being fully trained. In one such example, if the I3C bus is shared, then the registers are shadowed so that host can read without interrupting RCD operations. In one example, a BMC can also read the status of the QCS training by exposing calibration status register through I3C.

Thus, the RCD-controlled QCS training method can use sideband communication and an inbuilt RCD hardware state machine to perform the training autonomously to avoid host interactions and to reduce training time during boot.

FIGS. 7A-7B illustrate a flow diagram of an example of a method of RCD-controlled training of QCA. The method 700 is similar to the method 500 of FIG. 5, but with exemplary details specific to training QCA. In one example, an RCD autonomously trains the QCA signal lines after autonomously training the QCS signal lines.

In one example, the RCD is initialized for QCA training. In one example, initializing the RCD for QCA training involves disabling parity checking in the RCD and/or disabling a power down mode. In one example, the RCD is set to block commands to the data buffers (DB) and forward commands to DRAM as safety measures. The method 700 begins with the RCD entering into an autonomous QCA training mode (AQCATM), at block 701. In one example, the RCD is triggered to enter the AQCATM by the host (e.g., in response to one or more commands from the host to perform backside bus training generally, or QCA training specifically, or other commands from the host). For example, referring to FIGS. 2 and 3, the host memory controller 120 sends one or more commands to the RCD 121 to trigger the RCD to enter into a backside training mode. In the backside training mode, the RCD 121 autonomously trains QCA.

Referring again to FIG. 7A, in one example, the RCD triggers the DRAMs to enter into a QCA training mode (CATM), at block 702. In one example, causing the DRAMs to enter into a QCA training mode involves sending one or more commands over a local sideband bus. For example, referring to FIGS. 2 and 3, the QCA training logic 129 of RCD puts the DRAM in CATM by sending I3C commands to DRAM. In response to receiving the one or more commands from the RCD to enter into the QCA training mode, the DRAM enters the QCA training mode, at block 704.

In one example, unlike conventional training where the host generates the training patterns, the RCD generates patterns to drive on the QCA signal lines, at block 705. For example, referring to FIG. 3, the QCA training logic 129 can generate the training patterns. The pattern generated by the RCD can be fixed patterns or complex LFSR patterns. In one example, the function for CA training can be called twice (e.g., two sweeps), the first time for cycle alignment with a simple pattern, and the second time with a more complex pattern for fine tuning the timings. In one example of a simple fixed pattern (e.g., for the first sweep), only the QCA signal being trained will be asserted with a pattern (e.g., a pattern that is similar or the same as the CS_n pattern). In one such example, all other signals will be driven constantly high. In this example, when the target CA pulse is aligned to the CS assertion, the feedback coming back from the DRAM over the I3C bus read is a “1,” which is the result of the XOR of QCA [13:0] with 13 signals driving high, and 1 signal driving low. In one such example, centering is done in the middle of this “l's” region.

In another example with a complex QCA pattern (e.g., for the second CA sweep) all CA signals will be toggling with per-bit LFSR patterns to generate more stressful traffic (both in terms of intersymbol interference (ISI) as well as in terms of crosstalk between signals). In one such example, the pattern will have alternating LFSR assignment which creates two aggressors for each victim QCA signal line. According to one example, CS_n toggles at the most once every 4 tCK. The generated patterns and pattern controls that indicate what patterns to generate can be stored in a register on the RCD, at block 706. For example, referring to FIG. 3, the QCA training config register 312 can store pattern control information and the QCA training patterns register 314 can store the generated patterns.

Referring again to FIG. 7A, after generating the pattern, the RCD drives the QCA signal lines with the generated pattern, at block 707. The RCD then iteratively adjusts a timing parameter for QCA (e.g., sweeps a delay for QCA), at block 708. For example, referring to FIG. 3, the QCA training logic 129 of the RCD drives the QCA signal lines with the QCA training pattern. The QCA training logic 129 then trains QACA and QBCA (or in the case of more than two sides or groupings of DRAMs, QACA-QxCA) by sweeping the groups (e.g., from 0 to 127 with a programmable step size). In one such example, the RCD adjusts the QCA delay by modifying control words (e.g., register settings) in the RCD (e.g., control words RW12-RW1A(RCD)/RW82(DB) as defined in the in JEDEC DDR5RCD Specification). In one example, sweeping one group affects all the group QCA signals, and the way the RCD controls which signal edges are found is with the pattern.

Referring again to FIG. 7A, while the RCD is sweeping a timing parameter for QCA, the DRAM samples the QCA signals, at block 710. In one example, once the DRAM has CATM enabled, the DRAM device begins sampling on every rising CK edge, starting with a rising edge of clock signal after a delay of tCATM_Entry. In one such example, the RCD and/or the DRAM can be programmed to count the number of samples and programmed with a sampling or counting window (e.g., how long the DRAM has to sample the QCA signal lines). Programming the RCD with a sampling window or other training parameters can involve programming a QCA training configuration register (e.g., register 312 of FIG. 3). Programming the DRAM with training configuration details can involve programming a training configuration register (e.g., register 182 of FIG. 1). In one example, the DRAM stores information from the training, such as pass/fail data, in a register on the DRAM, at block 712. For example, referring to FIG. 1, the DRAM sampling and feedback logic 180 stores the pass/fail data in a register (e.g., the register 182).

In one example, after iteratively adjusting the timing parameter for QCA, the RCD receives feedback from the DRAM through the I3C/LPBK pins by doing an I3C read. For example, referring to FIG. 7A, the RCD sends one or more commands to the DRAM via a sideband bus to read feedback, at block 714. For example, referring to FIGS. 2 and 3, the QCA training logic 129 sends one or more read commands over the local I3C bus to the DRAM via the I3C pins (LSDA and LSCL). The DRAM receives the read command from the RCD, at block 716, and sends training feedback to the RCD via the sideband bus, at block 720. For example, the DRAM sends pass/fail data for one or more samples captured by the DRAM. As mentioned above, the pass/fail data can be provided to the RCD for every delay from the sweep, in aggregate, or as an average. In one example, the DRAM can provide its feedback with the help of in-band I3C interrupts (IBI) in case of any errors, status, or alert conditions.

Referring again to FIG. 7A, once the RCD receives the training feedback from the DRAM via the sideband bus, at block 718, the RCD can store the feedback at block 722. For example, referring to FIG. 3, the QCA training logic 129 can store the training feedback in a QCA training status register (e.g., register 316). In one example, the RCD counts errors and stores failure details (Cal status) for debug purposes in the QCA training status register. In one example, the RCD performs an I3C read for every timing point. In another example, to reduce the number of I3C reads, the samples are stored locally within DRAM itself and aggregated or averaged after a timing point. The average or aggregation can then be output by the DRAM as a single value over the local I3C bus. In one such example, the RCD stores the aggregated or averaged final results per QCA signals for each subchannel. In one example, in contrast with conventional systems, the RCD can receive feedback in parallel from all ranks being trained.

The RCD also determines a timing parameter value to use for QCA based on the training feedback and programs the timing parameter for each QCA, at block 724. For example, referring to FIG. 3, the QCA training logic 129 determines the delay that that is optimal based on the training feedback and programs a QCA configuration register 320 to select that value. In one example, to determine a timing parameter value to use for the QCA signal lines, the RCD determines the QCA edges per DRAM. Depending on the pattern, a “0” or “1” result may be considered a “pass.” In one example, the RCD determines the composite QCA edges per group (e.g., QACA and QBCA) across all ranks and DRAMs within the sub-channel/group (the RCD can check group to DQ mappings based on raw card connectivity). In one such example, the RCD determines the composite eye of the passing region across all DRAMs in the rank and centers the QCA timing based on that result. Referring to FIG. 3, the QCA logic 129 programs the QCA delay settings in the QCA config register 320.

Once the timing parameter is programmed, the RCD can also perform a sweep of the reference voltage for QCA (VrefCA). For example, referring to FIG. 7B, the RCD can iteratively adjust a VrefCA parameter, at block 726. In one example, iteratively adjusting the VrefCA parameter involves sending write commands to one or more registers in the DRAM to adjust the VrefCA parameter. In one example, the VrefCA parameter swept by the RCD is the voltage level. The VrefCA voltage level can be indicated as a value relative to VDD (e.g., a percentage or other function of VDD). The DRAM samples the QCA signal, at block 728, and stores pass/fail data, at block 730.

The RCD can then request training feedback from the DRAM by sending one or more commands (e.g., a read command) over the sideband bus, at block 734. The DRAM receives the read command from the RCD, at block 736, and sends the requested training feedback to the RCD via the sideband bus, at block 740. The RCD receives the training feedback for the VrefCA sweep, at block 738, and stores the training feedback from the DRAM, at block 742. The RCD can then program the VrefCA parameter based on the training feedback, at block 744.

The RCD can then trigger the DRAM to exit from the CATM mode, at block 746. Triggering the DRAM to exit from the CATM mode can involve, for example, the RCD sending one or more commands to the DRAM over the I3C bus to trigger the exit from CATM. In response to the command from the RCD, the DRAM exits CATM, at block 748. In one such example, the RCD causes the DRAM to exit the CA training mode by sending NOP commands and asserting CS for 2 cycles in a row.

The RCD can train QCA for all ranks in parallel, or one rank at a time. For example, if the RCD is training one rank at a time, the RCD causes the DRAMs in a particular rank to exit the CATM and moves on to the other rank to repeat operations 702-746. After training all ranks, the RCD exits the AQCATM on the RCD, at block 750, and can program the RCD with the final results (e.g., corresponding delays for each QCA, setup and hold time for each QCA, or other final information from training). In one example, the host can read the status of the QCA training through the I3C bus (e.g., the host I3C bus) due to the DQ bus not being fully trained. In one such example, if the I3C bus is shared, then the registers are shadowed so that host can read without interrupting RCD operations. In one example, the RCD can use In-band Interrupt (IBI) or the ALERT_N pin to provide feedback from the RCD to the host to provide faster feedback in some cases when I3C is not sufficiently fast. In one example, a BMC can also read the status of the QCA training by exposing calibration status register through I3C.

Therefore, in one example, in an autonomous backside QCA training mode (AQCATM), the RCD has internal hardware logic (e.g., state machine logic) to perform the entire training for QCA without host intervention. In one example, the RCD generates the required patterns for each of the QCA signals and drives each of the QCA signals with the specific pattern. In one example, the RCD also sweeps the delay for a particular QCA signal and identifies the left and right edges with respect to QCK rising edge to identify which delay causes the QCK rising edge to be in the middle of the QCA UI to maximize setup and hold margin. In one example, the final results data is stored within the RCD for each of the CA signal. This can be accessed by the host with the help of I3C reads (sideband signaling).

Thus, the RCD can autonomously perform the backside QCS and QCA training, which can fully remove host intervention, save host cycles, and reduce training time for every boot. RCD-controlled QCS and QCA training also removes multiple MPC in-band commands and provides for the ability to read status from I3C when the DQ bus is not fully trained. The QCS and QCA training for all DIMMs and all ranks in the system can be done in parallel to save time. In conventional systems, the pass/fail data cannot be received from all ranks in parallel due to contention on the DQ bus for the feedback. In contrast, as the RCD is receiving feedback from each DRAM through the I3C bus, depending on how many results tracking registers are in the RCD, the RCD can gather the pass/fail data across all ranks essentially at the same time, according to one example. Furthermore, a one-dimensional (1D) Vref sweep can be done with the help of the I3C bus without needing to do JEDEC initialization.

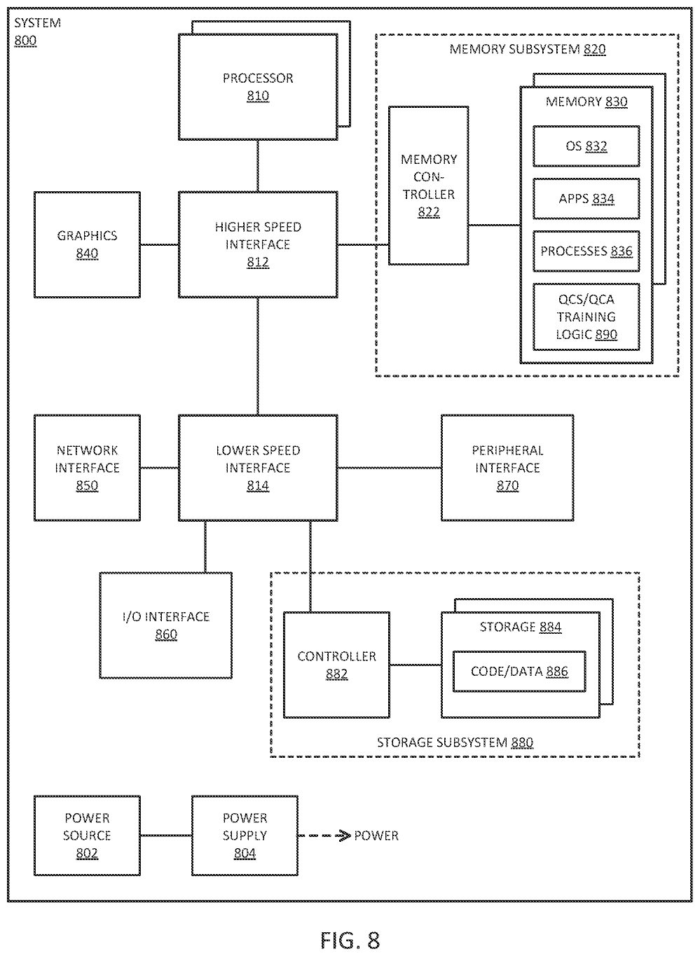

FIG. 8 is a block diagram of an embodiment of a computing system in which a memory system with autonomous RCD-controlled backside CS and CA training can be implemented. System 800 represents a computing device in accordance with any embodiment described herein, and can be a laptop computer, a desktop computer, a tablet computer, a server, a gaming or entertainment control system, a scanner, copier, printer, routing or switching device, embedded computing device, a smartphone, a wearable device, an internet-of-things device, or other electronic device.

System 800 includes processor 810, which provides processing, operation management, and execution of instructions for system 800. Processor 810 can include any type of microprocessor, central processing unit (CPU), graphics processing unit (GPU), processing core, or other processing hardware to provide processing for system 800, or a combination of processors. Processor 810 controls the overall operation of system 800, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one embodiment, system 800 includes interface 812 coupled to processor 810, which can represent a higher speed interface or a high throughput interface for system components that needs higher bandwidth connections, such as memory subsystem 820 or graphics interface components 840. Interface 812 represents an interface circuit, which can be a standalone component or integrated onto a processor die. Where present, graphics interface 840 interfaces to graphics components for providing a visual display to a user of system 800. In one embodiment, graphics interface 840 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one embodiment, the display can include a touchscreen display. In one embodiment, graphics interface 840 generates a display based on data stored in memory 830 or based on operations executed by processor 810 or both. In one embodiment, graphics interface 840 generates a display based on data stored in memory 830 or based on operations executed by processor 810 or both.

Memory subsystem 820 represents the main memory of system 800 and provides storage for code to be executed by processor 810, or data values to be used in executing a routine. Memory subsystem 820 can include one or more memory devices 830 such as read-only memory (ROM), flash memory, one or more varieties of random-access memory (RAM) such as DRAM, or other memory devices, or a combination of such devices. Memory 830 stores and hosts, among other things, operating system (OS) 832 to provide a software platform for execution of instructions in system 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software logic to provide functions for system 800. In one embodiment, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810.

While not specifically illustrated, it will be understood that system 800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus.

In one embodiment, system 800 includes interface 814, which can be coupled to interface 812. Interface 814 can be a lower speed interface than interface 812. In one embodiment, interface 814 represents an interface circuit, which can include standalone components and integrated circuitry. In one embodiment, multiple user interface components or peripheral components, or both, couple to interface 814. Network interface 850 provides system 800 the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can exchange data with a remote device, which can include sending data stored in memory or receiving data to be stored in memory.

In one embodiment, system 800 includes one or more input/output (I/O) interface(s) 860. I/O interface 860 can include one or more interface components through which a user interacts with system 800 (e.g., audio, alphanumeric, tactile/touch, or other interfacing). Peripheral interface 870 can include any hardware interface not specifically mentioned above. Peripherals refer generally to devices that connect dependently to system 800. A dependent connection is one where system 800 provides the software platform or hardware platform or both on which operation executes, and with which a user interacts.

In one embodiment, system 800 includes storage subsystem 880 to store data in a nonvolatile manner. In one embodiment, in certain system implementations, at least certain components of storage 880 can overlap with components of memory subsystem 820. Storage subsystem 880 includes storage device(s) 884, which can be or include any conventional medium for storing large amounts of data in a nonvolatile manner, such as one or more magnetic, solid state, or optical based disks, or a combination. Storage 884 holds code or instructions and data 886 in a persistent state (i.e., the value is retained despite interruption of power to system 800). Storage 884 can be generically considered to be a “memory,” although memory 830 is typically the executing or operating memory to provide instructions to processor 810. Whereas storage 884 is nonvolatile, memory 830 can include volatile memory (i.e., the value or state of the data is indeterminate if power is interrupted to system 800). In one embodiment, storage subsystem 880 includes controller 882 to interface with storage 884. In one embodiment controller 882 is a physical part of interface 814 or processor 810 or can include circuits or logic in both processor 810 and interface 814.

Power source 802 provides power to the components of system 800. More specifically, power source 802 typically interfaces to one or multiple power supplies 804 in system 800 to provide power to the components of system 800. In one embodiment, power supply 804 includes an AC to DC (alternating current to direct current) adapter to plug into a wall outlet. Such AC power can be renewable energy (e.g., solar power) power source 802. In one embodiment, power source 802 includes a DC power source, such as an external AC to DC converter. In one embodiment, power source 802 or power supply 804 includes wireless charging hardware to charge via proximity to a charging field. In one embodiment, power source 802 can include an internal battery or fuel cell source.

In one example, the memory 830 includes one or more buffered DIMMs, each having an RCD with QCS/QCA training logic 890. In one example, the logic 890 of the RCD autonomously trains the QCS and/or QCA signal lines in accordance with examples described herein.

Examples of autonomous RCD-controlled QCS and QCA training follow.

Example 1: A device to buffer signals between a memory controller and DRAM, the device including hardware logic to train one or more signal lines between the device and the DRAM. The hardware logic is to: trigger the DRAM to enter a training mode to train the one or more signal lines, drive the one or more signal lines with patterns, iteratively adjust a timing parameter for the one or more signal lines, and input/output (I/O) interface logic to receive training feedback from the DRAM over a sideband bus.

Example 2: The device of example 1, wherein: the one or more signal lines include one or more chip select (CS) signal lines or one or more command/address (CA) signal lines.

Example 3: The device of examples 1 or 2, wherein: the DRAM is included on a memory module, and the hardware logic is to train the one or more signal lines for multiple sides of the memory module in parallel, wherein the multiple sides include multiple copies of the same type of signal lines to different DRAMs on the memory module.

Example 4: The device of any of examples 1-3, wherein the hardware logic is to: receive an indication from the memory controller to autonomously train one or more signal lines between the device and the DRAM.

Example 5: The device of any of examples 1-4, wherein the hardware logic is to trigger the DRAM to enter the training mode with one of more commands over the sideband bus.

Example 6: The device of any of examples 1-5, further including one or more registers to store a value for the timing parameter for the one or more signal lines, wherein the hardware logic is to write the value for the timing parameter based on the training feedback received over the sideband bus.

Example 7: The device of example 6, wherein: the hardware logic is to receive the training feedback from the DRAM over the sideband bus prior to data bus (DQ) training.

Example 8: The device of any of examples 1-7, wherein: the training feedback is to be received in response to a read command sent to the DRAM over the sideband bus.

Example 9: The device of example 8, wherein: the training feedback from the DRAM includes pass/fail data for one or more samples captured by the DRAM.

Example 10: The device of example 8, wherein: the hardware logic is to receive the training feedback over the sideband bus for each sample captured by the DRAM in a sampling window.

Example 11: The device of example 8, wherein: the hardware logic is to receive the training feedback as an aggregate or average for samples captured by the DRAM in a sampling window.

Example 12: The device of any of examples 1-11, wherein: the hardware logic is to receive the training feedback over the sideband bus from multiple DRAMs in parallel.

Example 13: The device of any of examples 1-12, further including one or more registers to store the training feedback from the DRAM.

Example 14: The device of any of examples 1-13, wherein the hardware logic to train the one or more signal lines is to: after programming the timing parameter for the one or more signal lines, send one or more commands over the sideband bus to iteratively adjust Vref values for the signal lines, receive Vref training feedback from the DRAM, and program Vref based on the Vref training feedback.

Example 15: The device of any of examples 1-14, wherein: the device includes a registering clock driver (RCD).

Example 16: The device of any of examples 1-15, wherein: the device includes a CXL buffer.

Example 17: The device of any of examples 1-16, wherein: the sideband bus is an I3C sideband bus.

Example 18: A memory device including: memory cells to store data, and hardware logic to: receive one or more commands from a registering clock driver (RCD) over a sideband bus to enter a training mode to train one or more signal lines, receive patterns over the one or more signal lines, capture samples from the one or more signal lines, store training feedback about the samples, and send the training feedback to the RCD over the sideband bus.

Example 19: The memory device of example 18, wherein the training feedback about the samples includes one or more of: total count of the samples captured, an indication of start and stop time for the samples, and pass/fail information.

Example 20: A system including: a memory controller and one or more buffered dual inline memory modules (DIMMs) coupled with the memory controller. Each of the buffered DIMMs includes a plurality of DRAM devices and a registering clock driver (RCD) between the memory controller and the plurality of DRAM devices. The RCD includes logic to train one or more signal lines between the RCD and the DRAM devices, including to: trigger the DRAM devices to enter a training mode to train the one or more signal lines, drive the one or more signal lines with patterns, iteratively adjust a delay for the one or more signal lines, receive training feedback from the DRAM over a sideband bus, and program the delay for the one or more signal lines based on the training feedback.

Example 21: The system of example 20, wherein the plurality of DIMM's RCDs are to train the one or more signal lines in parallel.

Example 22: The system of examples 20 or 21, wherein the RCD is in accordance of any of examples 1-17.

Example 23: The system of any of examples 20-22, wherein the DRAM devices are in accordance with examples 18 or 19.

Example 24: A memory module including multiple DRAM devices, and a registering clock driver (RCD) to buffer signals between a memory controller and the DRAM devices. The RCD includes hardware logic to train one or more signal lines between the device and the DRAM, including to: trigger the DRAM to enter a training mode to train the one or more signal lines, drive the one or more signal lines with patterns, iteratively adjust a timing parameter for the one or more signal lines, and input/output (I/O) interface logic to receive training feedback from the DRAM over a sideband bus.

Example 25: The memory module of example 24, wherein the RCD is in accordance with any of examples 1-17.

Example 26: The memory module of Examples 24 or 25, wherein the DRAM devices are in accordance with examples 18 or 19.

Example 27: A method implemented by a registering clock driver (RCD) or other buffer device, the method including triggering a DRAM device to enter a training mode to train the one or more signal lines, driving the one or more signal lines with patterns, iteratively adjusting a timing parameter for the one or more signal lines, receiving training feedback from the DRAM device over a sideband bus, and programming the timing parameter for the one or more signal lines based on the training feedback.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

The hardware design embodiments discussed above may be embodied within a semiconductor chip and/or as a description of a circuit design for eventual targeting toward a semiconductor manufacturing process. In the case of the later, such circuit descriptions may take of the form of a (e.g., VHDL or Verilog) register transfer level (RTL) circuit description, a gate level circuit description, a transistor level circuit description or mask description or various combinations thereof. Circuit descriptions are typically embodied on a computer readable storage medium (such as a CD-ROM or other type of storage technology).

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A device to buffer signals between a memory controller and DRAM, the device comprising:
hardware logic to:
train one or more signal lines between the device and the DRAM, including to:
trigger the DRAM to enter a training mode to train the one or more signal lines,
drive the one or more signal lines with patterns,
iteratively adjust a timing parameter for the one or more signal lines; and
input/output (I/O) interface logic to receive training feedback from the DRAM over a sideband bus.

2. The device of claim 1, wherein:
the one or more signal lines include one or more chip select (CS) signal lines or one or more command/address (CA) signal lines.

3. The device of claim 1, wherein:
the DRAM is included on a memory module; and
the hardware logic is to train the one or more signal lines for multiple sides of the memory module in parallel, wherein the multiple sides include multiple copies of the same type of signal lines to different DRAMs on the memory module.

4. The device of claim 1, wherein the hardware logic is to:
receive an indication from the memory controller to autonomously train one or more signal lines between the device and the DRAM.

5. The device of claim 1, wherein:
the hardware logic is to trigger the DRAM to enter the training mode with one of more commands over the sideband bus.

6. The device of claim 1, further comprising:
one or more registers to store a value for the timing parameter for the one or more signal lines;
wherein the hardware logic is to write the value for the timing parameter based on the training feedback received over the sideband bus.

7. The device of claim 6, wherein:
the hardware logic is to receive the training feedback from the DRAM over the sideband bus prior to data bus (DQ) training.

8. The device of claim 1, wherein:
the training feedback is to be received in response to a read command sent to the DRAM over the sideband bus.

9. The device of claim 8, wherein:
the training feedback from the DRAM includes pass/fail data for one or more samples captured by the DRAM.

10. The device of claim 8, wherein:
the hardware logic is to receive the training feedback over the sideband bus for each sample captured by the DRAM in a sampling window.

11. The device of claim 8, wherein:
the hardware logic is to receive the training feedback as an aggregate or average for samples captured by the DRAM in a sampling window.

12. The device of claim 1, wherein:
the hardware logic is to receive the training feedback over the sideband bus from multiple DRAMs in parallel.

13. The device of claim 1, further comprising:
one or more registers to store the training feedback from the DRAM.

14. The device of claim 1, wherein the hardware logic to train the one or more signal lines is to:
after programming the timing parameter for the one or more signal lines, send one or more commands over the sideband bus to iteratively adjust Vref values for the signal lines;
receive Vref training feedback from the DRAM; and
program Vref based on the Vref training feedback.

15. The device of claim 1, wherein:
the device includes a registering clock driver (RCD).

16. The device of claim 1, wherein:
the device includes a CXL buffer.

17. The device of claim 1, wherein:
the sideband bus is an I3C sideband bus.

18. A memory device comprising:
memory cells to store data; and
hardware logic to:
receive one or more commands from a registering clock driver (RCD) over a sideband bus to enter a training mode to train one or more signal lines,
receive patterns over the one or more signal lines,
capture samples from the one or more signal lines,
store training feedback about the samples, and
send the training feedback to the RCD over the sideband bus.

19. The memory device of claim 18, wherein:
the training feedback about the samples comprises one or more of: total count of the samples captured, an indication of start and stop time for the samples, and pass/fail information.

20. A system comprising:
a memory controller; and
one or more buffered dual inline memory modules (DIMMs) coupled with the memory controller, each of the buffered DIMMs including:
a plurality of DRAM devices, and
a registering clock driver (RCD) between the memory controller and the plurality of DRAM devices, the RCD including hardware logic to:
train one or more signal lines between the RCD and the DRAM devices, including to:
trigger the DRAM devices to enter a training mode to train the one or more signal lines,
drive the one or more signal lines with patterns,
iteratively adjust a delay for the one or more signal lines,
receive training feedback from the DRAM over a sideband bus, and
program the delay for the one or more signal lines based on the training feedback.

21. The system of claim 20, wherein:
wherein the plurality of DIMM's RCDs are to train the one or more signal lines in parallel.
